(19) United States
(12) Patent Application Publication
(10) Pub. No.: US 2024/0145633 A1
(43) Pub. Date: May 2, 2024

(54) OPTOELECTRONIC SEMICONDUCTOR COMPONENT, AND METHOD FOR PRODUCING AT LEAST ONE OPTOELECTRONIC SEMICONDUCTOR COMPONENT

(71) Applicant: ams-OSRAM International GmbH, Regensburg (DE)

(72) Inventors: Matin Mohajerarni, Regensburg (DE); Alexander Pfeuffer, Regensburg (DE); Dominik Scholz, Bad Abbach (DE)

(21) Appl. No.: 18/279,645

(22) PCT Filed: Feb. 15, 2022
(86) PCT No.: PCT/EP2022/053622

§ 371 Date: Aug. 31, 2023

(30) Foreign Application Priority Data
Mar. 3, 2021 (DE) 10 2021 202 026.7

(51) Int. Cl. H01L 33/38; H01L 33/14; H01L 33/20; H01L 33/40

(52) U.S. Cl. CPC H01L 33/385; H01L 33/14; H01L 33/20; H01L 33/382; H01L 33/40; H01L 2933/0016

(57) ABSTRACT

In an embodiment an optoelectronic semiconductor component includes a layer stack having a side face or a plurality of side faces including a first side region delimiting a first semiconductor region sideways and a second side region partially delimiting a second side region sideways and a first main face and a second main face lying opposite the first main face, the one or more side faces connecting the first main face and the second main face to one another. The component further includes a first contact configured for electrical contacting the first semiconductor region, a second contact configured for the electrical contacting of the second semiconductor region and a dielectric layer arranged between the second contact and the layer stack, wherein the second contact is configured for horizontal current injection into the second semiconductor region.

### CROSS-REFERENCE TO RELATED APPLICATIONS

This patent application is a national phase filing under section 371 of PCT/EP2022/053622, filed Feb. 15, 2022, which claims the priority of German patent application 102021202026.7, filed Mar. 3, 2021, each of which is incorporated herein by reference in its entirety.

### TECHNICAL FIELD

An optoelectronic semiconductor component and a method for the production thereof are provided. For example, the optoelectronic semiconductor component is a micro-LED chip, the dimensions and luminous width of which lie in the micrometer range.

### BACKGROUND

Light-emitting diode (LED) chips which have etched blind holes for the electrical contacting of, for example, n-conductive semiconductor layers, in order to make the semiconductor layers electrically accessible, are known. A metal contact may in this case respectively be arranged in the blind holes. An area of the LED chip intended for the generation of radiation is reduced by the blind hole, or the metal contact, which therefore leads to a lower radiation efficiency of the LED chip. Since the metal contacts cannot be arbitrarily miniaturized, when miniaturizing the LED chip the problem may arise that the radiation efficiency decreases further.

### SUMMARY

Embodiments provide an efficient optoelectronic semiconductor component. Further embodiments provide a method for producing an efficient optoelectronic semiconductor component.

According to at least one embodiment of an optoelectronic semiconductor component, it comprises a layer stack which has a first semiconductor region of a first conductivity type, a second semiconductor region of a second conductivity type, and an active zone arranged between the first and second semiconductor regions. For example, the first semiconductor region is a p-doped region and the second semiconductor region is an n-doped region. Furthermore, the active zone is preferably intended to generate electromagnetic radiation. In the present case, the term “electromagnetic radiation” refers in particular to infrared, visible and/or ultraviolet electromagnetic radiation.

Furthermore, the layer stack comprises one or more side faces, that is to say at least one side face respectively having a first side region, which delimits the first semiconductor region sideways, and a second side region, which partially delimits the second side region sideways, as well as a first main face and a second main face lying opposite the first main face, the one or more side face(s) connecting the first main face and the second main face to one another. For example, the layer stack has precisely one side face when it is cylindrically configured. Further, the layer stack has a plurality of side faces when it is configured as a polyhedron.

The active zone may be arranged in a region of the layer stack which is delimited sideways by at least one first side region. The first side region may directly adjoin the first main face. Furthermore, the at least one second side region may directly adjoin the second main face.

For example, the first main face is a surface of the layer stack arranged on the side of the first semiconductor region, and the second main face is a surface of the layer stack arranged on the side of the second semiconductor region. A major part of the radiation generated may emerge from the semiconductor component on the side of the second main face.

According to at least one embodiment, the second semiconductor region is arranged on a front side, which is intended for the emission of radiation, and the first semiconductor region is arranged on a rear side of the optoelectronic semiconductor component, which lies opposite the front side.

Further, the optoelectronic semiconductor component comprises a first contact means, which is arranged on the first main face and is intended for the electrical contacting of the first semiconductor region, and a second contact means, which is arranged on the at least one side face and is intended for the electrical contacting of the second semiconductor region. In particular, the second contact means is an electrically conductive edge layer, which is arranged on the layer stack and extends from the first main face over a first side region as far as a second side region.

In addition, the optoelectronic semiconductor component comprises a dielectric layer arranged between the second contact means and the layer stack, at least one second side region being at least partially not covered by the dielectric layer and the second contact means covering the region not covered by the dielectric layer.

According to at least one embodiment, the second main face is substantially, that is to say within the scope of usual production tolerances, not covered by the second contact means. The second contact means is intended in particular for horizontal current injection into the second semiconductor region.

According to at least one embodiment, the dielectric layer covers at least one first side region. Preferably, all first side regions present are covered, in particular fully, by the dielectric layer. The dielectric layer ensures, in particular, electrical insulation of a p-n junction of the active zone.

The dielectric layer may consist of a single layer. Alternatively, the dielectric layer may have a plurality of layers, in particular with an alternating refractive index. In this case, the dielectric layer may additionally have a mirror function.

As materials for the dielectric layer, oxide and nitride compounds, for instance AlxOy, SiOx, SixNy, NbOx, TiOx, HfOx, TaOx, AlxNy and TixNy, as well as organic polymers, for instance parylene, BCB, silicones, siloxanes, photoresists, spin-on glasses, organic-inorganic hybrid materials, epoxides and acrylics, may be envisioned.

The active zone may contain a sequence of individual layers by means of which a quantum well structure, in particular a single quantum well structure (SQW) or multiple quantum well structure (MQW), is formed.

Furthermore, the first and second semiconductor regions may have one or more semiconductor layers. For the semiconductor layers of the semiconductor regions and of the active zone, materials based on nitride, phosphide or arsenide compound semiconductors may be considered. In the present context, “based on nitride, phosphide or arsenide compound semiconductors” signifies that the semiconductor layers contain AlₙGaₘIn₁₋ₙ₋ₘN, AlₙGaₘIn₁₋ₙ₋ₘP or AlₙGaₘIn₁₋ₙ₋ₘAs, where 0≤n≤1, 0≤m≤1 and n+m≤1. This material need not necessarily have a mathematically precise composition according to the formula above. Rather, it may have one or more dopants or additional constituents which do not substantially alter the characteristic physical properties of the AlₙGaₘIn₁₋ₙ₋ₘN, AlₙGaₘIn₁₋ₙ₋ₘP or AlₙGaₘIn₁₋ₙ₋ₘAs material. For the sake of simplicity, however, the formula above involves only the essential constituents of the crystal lattice (Al, Ga, In, P or As), even though they may be partially replaced with small amounts of further substances.

According to at least one embodiment, the optoelectronic semiconductor component is a micro-LED chip. The micro-LED chip may have a first lateral extent which is for example between 5 μm and 20 μm, in particular 10 μm, as specified along a first lateral direction. Further, a second lateral extent of the micro-LED chip, as specified along a second lateral direction, may be of the same size as the first lateral extent and may, for example, be between 5 μm and 20 μm, in particular 10 μm. Furthermore, a height of the optoelectronic semiconductor component, or micro-LED chip, as specified along a vertical direction, may for example be between 1 μm and 2 μm. The second lateral direction may be perpendicular to the first lateral direction. Further, the vertical direction may be perpendicular to the first and second lateral directions.

According to at least one embodiment, the second semiconductor region has a part extending laterally beyond the first semiconductor region. In this case, the part extending laterally beyond the first semiconductor region may be delimited by at least one second side region. In particular, the part extending laterally beyond the first semiconductor region is delimited sideways by the at least one second side region, which is at least partially not covered by the dielectric layer.

The layer stack may have a first part configured in the form of a mesa, which has at least the first semiconductor region, and a second part configured in the form of a mesa, which at least partially protrudes laterally beyond the first part configured in the form of a mesa and has a part of the second semiconductor region.

According to at least one embodiment, the second semiconductor region has a current spreading layer, which is formed from semiconductor material and is delimited sideways by at least one second side region. For example, the current spreading layer is an n-doped semiconductor layer with heavy doping, for instance between 10¹⁹*cm⁻³ and 10²⁰*cm⁻³, which ensures good current spreading and low contact resistances. For example, silicon may be envisioned as a dopant. The current spreading layer may be configured to be relatively thick, with a thickness in the range of one micrometer.

According to at least one embodiment, the one or more side face(s) is/are at least mostly covered by the second contact means.

The second contact means may contain or consist of at least one of the following materials: TCO, metal, graphene. For example, the following metals or metal compounds may be envisioned: Ti, Al, AuGe. “TCO” refers to a transparent conductive oxide (abbreviated to “TCO”). TCOs are transparent conductive materials, generally metal oxides, for example zinc oxide, tin oxide, cadmium oxide, titanium oxide, indium oxide or indium tin oxide (ITO). Besides binary metal-oxygen compounds, for example ZnO, SnO₂ or In₂O₃, the group of TCOs also includes ternary metal-oxygen compounds, for example Zn₂SnO₄, CdSnO₃, ZnSnO₃, MgIn₂O₄, GaInO₃, Zn₂In₂O₅ or In₄Sn₃O₁₂ or mixtures of different transparent conductive oxides. Furthermore, TCOs do not necessarily correspond to a stoichiometric composition, and may also be p- or n-doped.

In one advantageous configuration, the second contact means forms mirroring of the layer stack. In this way, the radiation generated by the active zone may advantageously be directed onto the second main face. In this case, the second contact means may contain or consist of a metal, in which case Rh, Al, Cr, Ti, Pt, W, Au and Ni may in particular be envisioned as metals.

According to at least one embodiment, the optoelectronic semiconductor component can be electrically connected externally on one side of the first main face by means of the first contact means and the second contact means, the first contact means serving as a contact pad of the first conductivity type and the second contact means on the first main face serving as a contact pad of the second conductivity type. For example, the first contact means may be arranged centrally on the first main face and be surrounded on all sides by the second contact means.

The first and second contact means may be formed from different materials. For example, the first contact means contains or consists of a metal or a metal compound.

The means for the electrical contacting of the first and second semiconductor regions, comprising the first and second contact means, are arranged outside the layer stack so that no area is “used up” for the contacting and the surface efficiency, or radiation efficiency, can thereby be improved. Furthermore, the problems occurring on the metal contacts in the case of conventional components, for example dark spots and so-called “current crowding”, may be prevented.

The method described below is suitable for the production of an optoelectronic semiconductor component or a multiplicity of optoelectronic semiconductor components of the type mentioned above. Features described in connection with the semiconductor component may therefore also be used for the method, and vice versa.

According to at least one embodiment of a method for producing at least one optoelectronic semiconductor component of the type mentioned above, it comprises:
providing a semiconductor wafer comprising a carrier and a semiconductor layer sequence, which is arranged on the carrier,
producing at least one layer stack by generating at least one first recess in the semiconductor wafer starting from a side of the semiconductor layer sequence facing away from the carrier and by generating at least one second recess in the semiconductor wafer starting from the first recess,
applying a dielectric layer onto the semiconductor wafer in such a way that at least one second side region of a side face of the layer stack is at least partially not covered by the dielectric layer,
applying an electrically conductive layer, which is intended to form a second contact means, onto the second dielectric layer in such a way that the electrically conductive layer covers the region of the second side region not covered by the dielectric layer,
the at least one second recess being at least partially delimited laterally by the at least one second side region.

According to at least one embodiment, the at least one first recess is laterally delimited by first side regions of neighboring layer stacks. Furthermore, the at least one second recess may be laterally delimited by second side regions of neighboring layer stacks.

According to at least one embodiment, the dielectric layer is generated before the at least one second recess is produced. In this case, the dielectric layer does not reach into the second recess so that the second side regions, which laterally delimit the second recess, are not covered by the dielectric layer.

For example, the at least one first recess may be configured to be wider than the second recess. Furthermore, the at least one first recess may extend, starting from the first main face, beyond the active zone in the vertical direction into a second semiconductor layer sequence intended for the production of the second semiconductor region. The second recess may be arranged after the first recess in the vertical direction and, for example, may extend beyond the current spreading layer into the second semiconductor layer sequence.

According to at least one embodiment, the first recess and the second recess are generated by means of etching, for example by anisotropic etching. For example, plasma etching may be envisioned as an etching method.

The optoelectronic semiconductor component is suitable particularly for display devices, video walls, vehicle headlamps and applications in the interior of vehicles.

### BRIEF DESCRIPTION OF THE DRAWINGS

Further advantages, advantageous embodiments and developments may be found from the following exemplary embodiments described in conjunction with the figures, in which:

FIG. 1A shows a schematic cross-sectional view of an intermediate product along a plane A-A (cf. FIG. 1B) in a method for producing an optoelectronic semiconductor component according to a first exemplary embodiment, FIG. 1B shows a schematic plan view of a detail of the intermediate product represented in FIG. 1A, and FIG. 1C shows a schematic cross-sectional view of an optoelectronic semiconductor component according to the first exemplary embodiment;

FIG. 2A shows a schematic cross-sectional view of a section of an intermediate product along a plane A-A (cf. FIG. 2B) in a method for producing an optoelectronic semiconductor component according to a second exemplary embodiment, and FIG. 2B shows a schematic plan view of the intermediate product; and

FIG. 3A shows a schematic cross-sectional view of an intermediate product along a plane A-A (cf. FIG. 3B) in a method for producing an optoelectronic semiconductor component according to a third exemplary embodiment, and FIG. 3B shows a schematic plan view of a section of the intermediate product represented in FIG. 3A.

In the exemplary embodiments and figures, elements which are the same or of the same type, or which have the same effect, may respectively be provided with the same reference signs. The elements represented and their size proportions with respect to one another are not necessarily to be regarded as true to scale; rather, individual elements may be represented exaggeratedly large for better representability and/or for better understanding.

### DETAILED DESCRIPTION OF ILLUSTRATIVE EMBODIMENTS

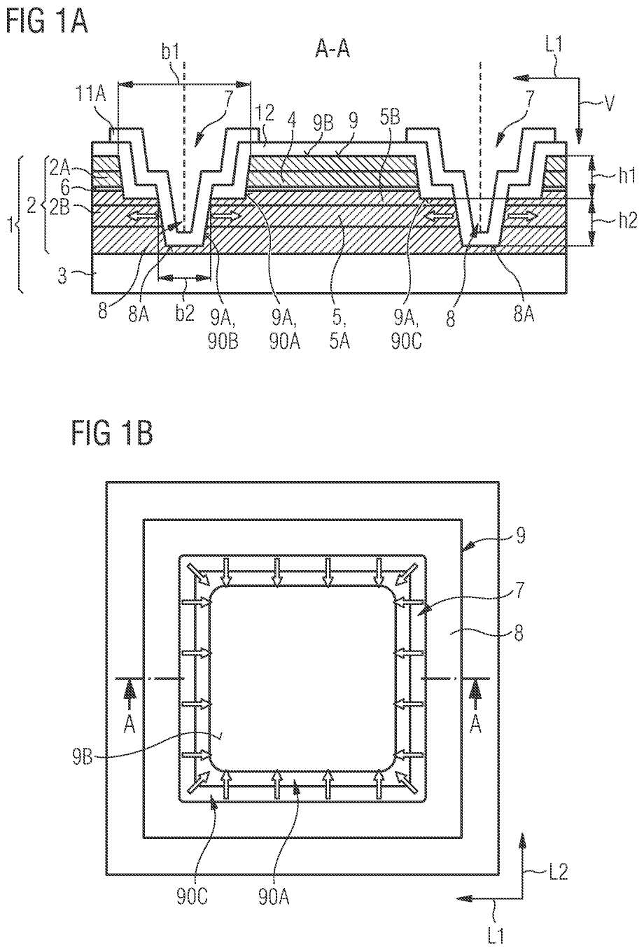

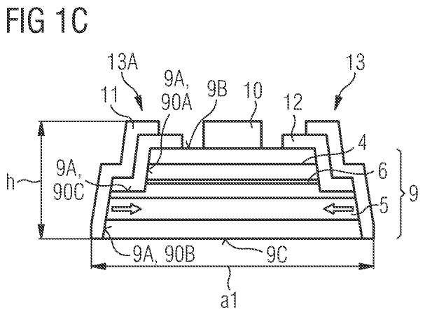

FIG. 1A shows an intermediate product in a method for producing an optoelectronic semiconductor component 13 according to a first exemplary embodiment (cf. FIG. 1C).

In order to produce the intermediate product, a semiconductor wafer 1 comprising a carrier 3 and a semiconductor layer sequence 2, which is arranged on the carrier 3, is provided. The semiconductor layer sequence 2 comprises a first semiconductor layer sequence 2A of a first conductivity type for the production of at least one first semiconductor region 4 of a layer stack 9, and a second semiconductor layer sequence 2B of a second conductivity type for the production of a second semiconductor region 5 of a semiconductor layer stack 9. Further, the semiconductor layer sequence 2 comprises an active zone 6 arranged between the first and second semiconductor layer sequences 2A, 2B. The second semiconductor layer sequence 2B is arranged after the first semiconductor layer sequence 2A in a vertical direction V. The carrier 3 is, for example, a growth substrate on which the semiconductor layer sequence 2 is epitaxially grown. For example, the carrier 3 may be formed from sapphire (Al₂O₃).

The semiconductor wafer 1 is structured in order to generate layer stacks 9. In this case, in order to produce a layer stack 9, a first recess 7 is introduced into the semiconductor wafer 1 starting from a side of the semiconductor layer sequence 2 facing away from the carrier 3. The first recess 7 may be configured in the form of a frame in a plan view of the semiconductor layer sequence 2 (cf. FIG. 1B). Further, the first recess 7 may have a cross section that tapers in the direction of the carrier 3. Furthermore, a second recess 8 is generated in the semiconductor wafer 1 starting from the first recess 7. The second recess 8 may also be configured in the form of a frame in a plan view of the semiconductor layer sequence 2 and have a cross section that tapers in the direction of the carrier 3. In this case, the first recess 7 is configured to be wider than the second recess 8. Further, the second recess 8 may be configured to be deeper than the first recess 7. In the first exemplary embodiment, the first recess 7 extends beyond the active zone 6 in the vertical direction V into the second semiconductor layer sequence 2B and ends before a current spreading layer 5A of the second semiconductor region 5. For example, the current spreading layer 5A may be formed from GaN and may be n-doped, and configured to be relatively thick with a thickness of about 1 μm. In particular, the first recess 7 ends in a spacer layer 5B of the second semiconductor layer sequence 2B.

In the layer stacks 9 formed in this way, the second semiconductor region 5 has a part that extends laterally beyond the first semiconductor region 4. The layer stacks 9 respectively have a first part configured in the form of a mesa, which comprises the first semiconductor region 4 and the active zone 6, and a second part configured in the form of a mesa, which protrudes laterally beyond the first part configured in the form of a mesa and comprises a part of the second semiconductor region 5.

For example, the first recess 7 is configured with a maximum width b1, that is to say with a maximum first lateral extent b1 as specified along a first lateral direction L1, of between about 2 μm and 3 μm. A height h1 of the first recess 7, as specified along the vertical direction, may be between 200 nm and 400 nm. Furthermore, the second recess 8 may be configured with a maximum width b2 of between about 1 μm and 2 μm. The height h2 of the second recess 8 may be between 600 nm and 800 nm.

The first recess 7 and the second recess 8 are generated for example by means of etching, for example anisotropic etching.

On a side of the semiconductor layer sequence 2 facing away from the carrier 3, a dielectric layer 12 is applied onto the semiconductor wafer 1, side faces 9A of the layer stack 9 respectively being covered by the dielectric layer 12. In particular, first side regions 90A of the side faces 9A, which respectively delimit the first semiconductor regions 4 laterally, or sideways, are fully covered by the dielectric layer 12. “Laterally” or “sideways” in this case denotes the lateral directions L1, L2 arranged transversely, in particular perpendicularly, with respect to the vertical direction V. In addition, the dielectric layer 12 is arranged on third side regions 90C arranged transversely with respect to the first side regions 90A, or on a bottom face of the first recess 7. Furthermore, a first main face 9B of the layer stack 9, arranged transversely with respect to the side faces 9A, is respectively covered fully by the dielectric layer 12.

The dielectric layer 12 is, in particular, generated before the second recess 8 is produced. Consequently, the dielectric layer 12 does not reach into the second recess 8 so that second side regions 90B of the side faces 9A, which laterally delimit a part of the second semiconductor regions 5, are not covered by the dielectric layer 12.

As mentioned above, the dielectric layer 12 may consist of a single layer. Alternatively, the dielectric layer 12 may have a plurality of layers, in particular with an alternating refractive index. As materials for the dielectric layer 12, oxide and nitride compounds, for instance AlxOy, SiOx, SixNy, NbOx, TiOx, HfOx, TaOx, AlxNy and TixNy, as well as organic polymers, for instance parylene, BCB, silicones, siloxanes, photoresists, spin-on glasses, organic-inorganic hybrid materials, epoxides and acrylics, may be envisioned.

The first recess 7 is laterally delimited by first side regions 90A of neighboring layer stacks 9. Furthermore, the second recess 8 is laterally delimited by second side regions 90B of neighboring layer stacks 9.

An electrically conductive layer 11A, which is intended to form a second contact means 11, is applied onto the dielectric layer 12. This is preferably done after the production of the second recess 8, the electrically conductive layer 11A covering regions of the second side regions 90B not covered by the dielectric layer 12. In particular, the electrically conductive layer 11A is applied fully onto a bottom face 8A of the second recess 8, onto the second side regions 90B and onto the dielectric layer 12, and is subsequently opened for the application of a first contact means 10. This may, for example, be done by means of an etching or lift-off process.

As may be seen from FIG. 1C, the dielectric layer 12 is also opened so that the first main face 9B has an uncovered region in which the first contact means 10, which is intended for the electrical contacting of the first semiconductor region 4, is arranged.

Furthermore, a second main face 9C of the layer stack 9, lying opposite the first main face 9B, is exposed. In particular, the carrier 3 is in this case removed. The semiconductor wafer 1 may be thinned starting from the carrier 3, at least as far as the bottom face 8A of the second recess 8, so that the layer stacks 9 connected by the second semiconductor region 5 can be separated from one another, or singulated.

For example, the exposure of the second main face 9C is carried out by means of polishing and/or etching and/or a laser lift-off process.

FIG. 1C shows an optoelectronic semiconductor component 13 which may be produced by means of a method as described in conjunction with FIGS. 1A and 1B. Features described in connection with the method may therefore also be used for the optoelectronic semiconductor component 13, and vice versa.

The optoelectronic semiconductor component 13 comprises a layer stack 9 which has a first semiconductor region 4 of a first conductivity type, a second semiconductor region 5 of a second conductivity type, and an active zone 6 arranged between the first and second semiconductor regions 4, 5, which is intended for example for the emission of electromagnetic radiation in the visible, ultraviolet or infrared spectral range.

For the semiconductor regions 4, 5 and the active zone 6, as well as semiconductor layers contained therein, as mentioned above materials based on nitride, phosphide or arsenide compound semiconductors may be considered. In the present context, “based on nitride, phosphide or arsenide compound semiconductors” signifies that the semiconductor regions 4, 5 and the active zone 6, or the semiconductor layers contained therein, contain AlₙGaₘIn₁₋ₙ₋ₘN, AlₙGaₘIn₁₋ₙ₋ₘP or AlₙGaₘIn₁₋ₙ₋ₘAs, where 0≤n≤1, 0≤m≤1 and n+m≤1.

The layer stack 9 comprises a plurality of side faces 9A, which respectively have a

first side region 90A, which delimits the first semiconductor region 4 sideways, and a second side region 90B, which partially delimits the second semiconductor region 5 sideways. Further, the layer stack 9 has a first main face 9B and a second main face 9C lying opposite the first main face 9B, the first side regions 90A and the second side regions 90B respectively being arranged transversely with respect to the first and second main faces 9B, 9C.

The optoelectronic semiconductor component 13 further comprises a first contact means 10, arranged at or on the first main face 9B, which is intended for the electrical contacting of the first semiconductor region 4, and a second contact means 11, arranged on the side faces 9A, which is intended for the electrical contacting of the second semiconductor region 5. By means of the second contact means 11, horizontal current injection may be carried out into the second semiconductor region 5 (indicated by arrows). For example, the second contact means 11 forms mirroring of the layer stack 9. In this way, the radiation generated by the active zone 6 may advantageously be directed onto the second main face 9C. In this case, the second contact means 11 may advantageously contain or consist of a metal, in which case Rh, Al, Cr, Ti, Pt, W, Au and Ni may in particular be envisioned as metals.

Furthermore, the optoelectronic semiconductor component 13 comprises a dielectric layer 12 arranged between the second contact means 11 and the layer stack 9, the second side regions 90B not being covered by the dielectric layer 12 and the second contact means 11 covering the regions not covered by the dielectric layer 12.

The first and second contact means 10, 11 allow electrical contacting of the semiconductor component 13 on its rear side 13A. The semiconductor component 13 can be electrically connected externally on its rear side 13A by means of the first and second contact means 10, 11.

The means for the electrical contacting of the first and second semiconductor regions 4, 5, comprising the first and second contact means 10, 11, are arranged outside the layer stack 9 so that no area is “used up” for the contacting and the surface efficiency, or radiation efficiency, can thereby be improved.

The optoelectronic semiconductor component 13 is a micro-LED chip. The semiconductor component 13 has a first lateral extent a1, as specified along the first lateral direction L1, which is for example between 5 μm and 20 μm, in particular about 10 μm. Further, a second lateral extent (not represented), as specified along the second lateral direction L2, may be of the same size as the first lateral extent a1 and may, for example, be between 5 μm and 20 μm, in particular 10 μm. Furthermore, a height h of the optoelectronic semiconductor component 13, as specified along the vertical direction V, may for example be between 1 μm and 2 μm.

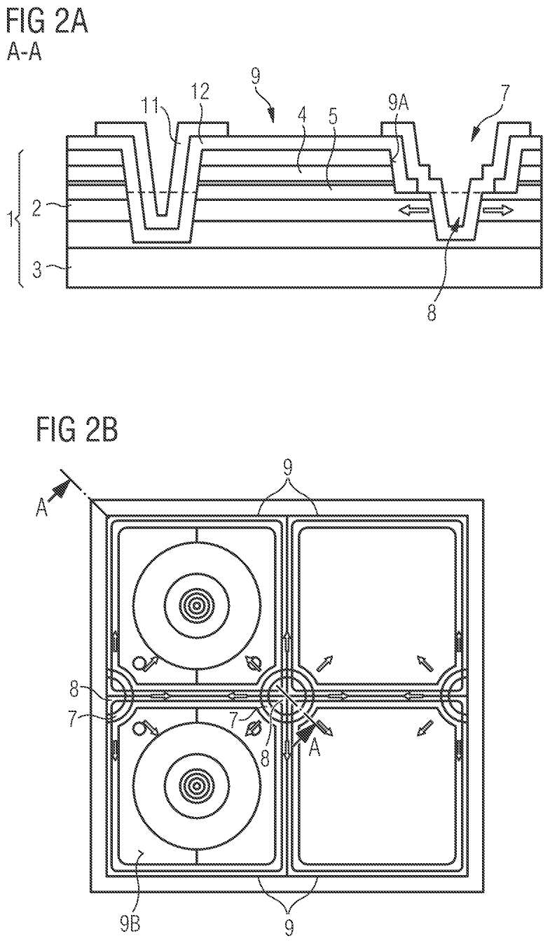

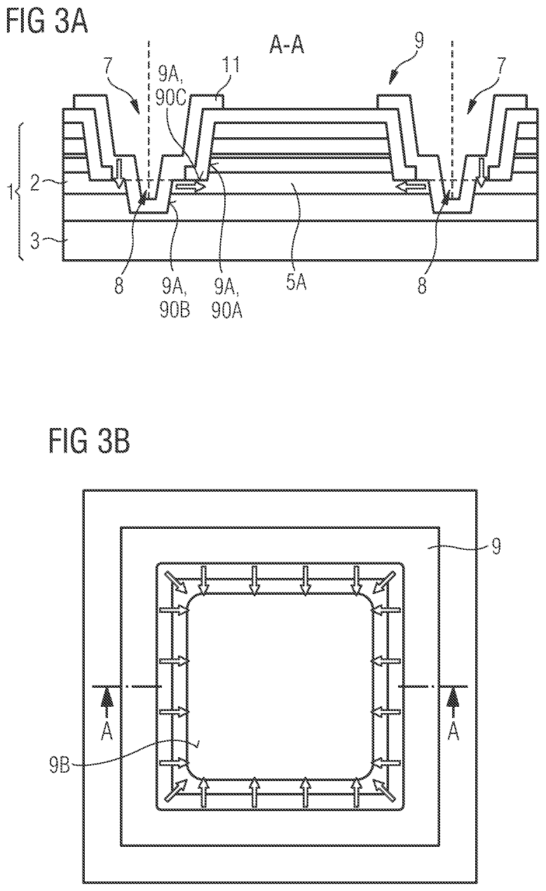

In the case of the exemplary embodiments represented in FIGS. 2A and 2B and in FIGS. 3A and 3B, primarily the differences from the first exemplary embodiment will be discussed. In other regards, all comments already made in connection with the first exemplary embodiment apply.

In the second exemplary embodiment, at least one first recess 7 is produced, which is not formed fully circumferentially, or in the form of a frame, but is introduced into the semiconductor wafer 1 in the form of a circular, elliptical or rectangular blind bore. As may be seen from FIG. 2B, the first recess 7 may be generated in mutually adjacent corner regions of neighboring layer stacks 9. A part of the second semiconductor layer region 5 which extends laterally beyond the first semiconductor region 4 is therefore present only in places.

The second exemplary embodiment offers the advantage that the first recess 7 may be configured to be wider than in the first exemplary embodiment, since the surface utilization in the case of the locally delimited first recess 7 becomes less. The wider first recess 7 allows the production of further structural edges on the side face 9A. For example, independent structures may be generated in order to structure the dielectric layer 12 by using a resist mask. In the second exemplary embodiment, it is possible to generate the first and second recesses 7, 8 before the dielectric layer 12 is applied.

In the third exemplary embodiment (cf. FIGS. 3A and 3B), the first recess 7 reaches further into the second semiconductor layer sequence 2B than in the first exemplary embodiment. The first recess 7 ends in the current spreading layer 5A, so that the current spreading layer 5A of the layer stack 9 is laterally delimited partially by the first side regions 90A and partially by the second side regions 90B. Furthermore, third side regions 90C are only partially covered by the dielectric layer 12 so that the second contact means 11 on the third side regions 90C is in direct contact with the second semiconductor region 5. This increases a contact area, which is particularly advantageous in the case of heavy currents. In addition to the horizontal current injection, vertical current injection may take place in this case (indicated by arrows).

In the third exemplary embodiment, the second recess 8 may be generated after the production of the dielectric layer 12, as in the first exemplary embodiment. By means of a photoresist layer that is used for the production of the second recess 8, the dielectric layer 12 is removed, for example by means of isotropic etching, at the transition to the second recess 8.

The description with the aid of the exemplary embodiments does not restrict the invention to this description. Rather, the invention comprises any new feature and any combination of features, which in particular includes any combination of features in the patent claims, even if this feature or this combination is not itself explicitly specified in the patent claims or the exemplary embodiments.

1.-15. (canceled)

16. An optoelectronic semiconductor component comprising:
a layer stack comprising:
a first semiconductor region of a first conductivity type,
a second semiconductor region of a second conductivity type,
an active zone arranged between the first and second semiconductor regions,
a side face or a plurality of side faces comprising a first side region delimiting the first semiconductor region sideways and a second side region partially delimiting the second side region sideways, and
a first main face and a second main face lying opposite the first main face, the one or more side faces connecting the first main face and the second main face to one another;
a first contact arranged on the first main face and configured for electrical contacting the first semiconductor region;
a second contact arranged on the one or more side faces and configured for the electrical contacting of the second semiconductor region; and
a dielectric layer arranged between the second contact and the layer stack,
wherein at least one second side region is at least partially not covered by the dielectric layer,
wherein the second contact covers a region not covered by the dielectric layer,
wherein the second semiconductor region comprises a current spreading layer, which is formed from a semiconductor material and which is delimited sideways by the at least one second side region, and
wherein the second contact is configured for horizontal current injection into the second semiconductor region.

17. The optoelectronic semiconductor component of claim 16, wherein the at least one second side region, which is at least partially not covered by the dielectric layer, delimits sideways a part of the second semiconductor region extending laterally beyond the first semiconductor region.

18. The optoelectronic semiconductor component of claim 16, wherein the layer stack has a first part forming a first mesa, which comprises at least the first semiconductor region, and a second part forming a second mesa, which at least partially protrudes laterally beyond the first part forming the first mesa and comprises a part of the second semiconductor region.

19. The optoelectronic semiconductor component of claim 18, wherein the dielectric layer covers at least one first side region.

20. The optoelectronic semiconductor component of claim 16, wherein the second main face is substantially not covered by the second contact.

21. The optoelectronic semiconductor component of claim 16, wherein the one or more side face are at least mostly covered by the second contact.

22. The optoelectronic semiconductor component of claim 16, wherein the second contact comprises a TCO, a metal or graphene.

23. The optoelectronic semiconductor component of claim 16, wherein the second contact consists of a TCO, a metal or graphene.

24. The optoelectronic semiconductor component of claim 16, wherein the second contact is a mirror for the layer stack.

25. The optoelectronic semiconductor component of claim 16, wherein the optoelectronic semiconductor component is externally contactable on the first main face by the first contact and the second contact.

26. The optoelectronic semiconductor component of claim i6, wherein the optoelectronic semiconductor component is a micro-LED chip having lateral dimensions in a range of between 5 μm and 20 μm, inclusive.

27. A method for producing at least one optoelectronic semiconductor component of claim 16, the method comprising:
providing a semiconductor wafer comprising a carrier and a semiconductor layer sequence arranged on the carrier;
producing at least one layer stack by forming at least one first recess in the semiconductor wafer starting from a side of the semiconductor layer sequence facing away from the carrier and by forming at least one second recess in the semiconductor wafer starting from the first recess;
applying the dielectric layer onto the semiconductor wafer such that at least one second side region of the side face of the layer stack is at least partially not covered by the dielectric layer; and
applying an electrically conductive layer configured to form the second contact onto the dielectric layer such that the electrically conductive layer covers the region of the second side region not covered by the dielectric layer,
wherein the at least one second recess is at least partially delimited laterally by the at least one second side region.

28. The method of claim 27, wherein the dielectric layer is generated before the at least one second recess is produced.

29. The method of claim 27, wherein the at least one first recess is wider than the second recess.

30. The method of claim 27, wherein the at least one first recess is laterally delimited by first side regions of neighboring layer stacks and the at least one second recess is laterally delimited by second side regions of neighboring layer stacks.

31. The method of claim 27, wherein the at least one first recess and the at least one second recess are generated by etching.
